(19) United States
(12) Patent Application Publication
(10) Pub. No.: US 2025/0309847 A1
(43) Pub. Date: Oct. 2, 2025

(54) A TRAVELLING-WAVE PARAMETRIC AMPLIFIER DEVICE FOR A QUANTUM COMPUTER

(71) Applicant: QET Sweden AB, Göteborg (SE)

(72) Inventors: Hampus RENBERG NILSSON, Göteborg (SE); Vitaly SHUMEIKO, Göteborg (SE); Anita FADAVI ROUDSARI, Göteborg (SE); Per DELSING, Landvetter (SE); Daryoush SHIRI, Göteborg (SE)

(21) Appl. No.: 18/863,936

(22) PCT Filed: May 2, 2023
(86) PCT No.: PCT/SE2023/050414

§ 371 Date: Nov. 7, 2024

(30) Foreign Application Priority Data
May 16, 2022 (SE) 2250580-4

(51) Int. Cl. H03F 19/00; G06N 10/40; H10N 60/12

(52) U.S. Cl. CPC H03F 19/00; G06N 10/40; H10N 60/12

(57) ABSTRACT

The present disclosure relates to a TWPA device (1) for a quantum computer having a two-band dispersion relation and being configured to implement 3-wave mixing. The TWPA device (1) comprises chained unit cells (ø), each one comprising a nonlinear inductance element (5) and a capacitor (6) connected to a ground (7) thereof. The unit cells (ø) further comprises one of a resonator circuit (8) and periodically modulated input parameters. The two-band dispersion relation is composed of a lower frequency band and an upper frequency band with a frequency-gap in-between. Further, the TWPA device (1) is configured to receive an amplification signal, receive a pump signal at said input (2). The pump signal having a frequency being in said upper frequency band and being at least ⅔ of a cut-off frequency of said TWPA device (1), or said pump signal having a frequency being in said lower frequency band, wherein a second harmonic thereof is within said frequency-gap.

### TECHNICAL FIELD

The present disclosure relates to a travelling-wave parametric amplifier (TWPA) device for a quantum computer. Further, the disclosure relates to a method for amplifying an amplification signal.

### BACKGROUND

In general, amplifiers are used to convert a signal with small power into a signal with a larger power. A specific type of amplifier called a travelling-wave parametric amplifier (TWPA) is used in several applications such as for satellite communication, radio astronomy and qubit readout in quantum computers. The TWPA provides the benefit of amplifying a wide band of signal frequencies while adding little noise, which allows for an improved signal-to-noise ratio for several signal frequencies. For conventional parametric amplifiers, a large microwave signal, usually called the pump, varies some parameter of the system, which then provides energy for the amplification.

A TWPA has a sharp cut-off frequency determined by the inductance and the capacitance of the unit cell. Further, TWPA's typically comprise of a large number of unit cells connected in series. Different TWPAs can utilize either 3-wave mixing that relies on a first order nonlinearity or 4-wave mixing that utilizes a second order nonlinearity. 3-wave mixing provides the advantage of advantage of requiring a smaller pump amplitude than 4-wave mixing, which in principle allows it to have a larger dynamic.

For a TWPA utilizing 3-wave mixing there are two effects than can reduce gain-phase mismatch and up-conversion. However, there is a challenge in the present art to provide a TWPA that utilizes 3-wave mixing while minimising up-conversion and phase-mismatch simultaneously.

Accordingly, there is a need in the art for a TWPA that utilizes 3-wave mixing while phase-mismatch and up-conversion are removed, or at least mitigated. More specifically there is a need for a TWPA based on 3-wave mixing that that minimises phase mismatch and up-conversion, in order to achieve high gain.

Even though some currently known solutions work well in some situations it would be desirable to provide an improved TWPA utilizing 3-wave mixing that fulfils requirements related to high-gain while minimising phase-mismatch and up-conversion.

### SUMMARY

It is therefore an object of the present disclosure to provide a TWPA device that mitigate, alleviate or eliminate the deficiencies and disadvantages of currently known solutions.

This object is achieved by means of a TWPA device and a method as defined in the appended claims.

The present disclosure is at least partly based on the insight that a TWPA device according to the present disclosure will minimise phase-mismatch and up-conversion thus providing a high gain. Thus, providing a TWPA device that performs with improved reliability.

The present disclosure relates to a travelling-wave parametric amplifier (TWPA) device for a quantum computer (that is based on superconducting qubits), wherein the TWPA has a two-band dispersion relation and is configured to implement 3-wave mixing in said two-band dispersion relation. The TWPA device comprises a plurality of chained unit cells, each unit cell comprising a nonlinear inductance element and a capacitor connected to a ground thereof, wherein said chained unit cells further comprises one of:
(i) a resonator circuit arranged in each of said plurality of unit cells and
(ii) periodically modulated input parameters.

Moreover, the two-band dispersion relation is composed/comprises of a lower frequency band and an upper frequency band with a frequency-gap in-between said upper and lower frequency bands. Further, the TWPA device is configured to: receive an amplification signal for amplification, at an input of said TWPA device and receive a pump signal at said input for providing energy to said amplification signal. The pump signal having a frequency being in said upper frequency band and being at least ⅔ of a cut-off frequency of said TWPA device, or the pump signal having a frequency being in said lower frequency band, wherein a second harmonic thereof is within said frequency-gap.

An advantage of the TWPA device of the present disclosure is that it provides a high gain, which may be exponential. In other words, a TWPA based on 3-wave mixing with a high gain that grows exponentially with the length of the TWPA. In other words, the TWPA device of the present disclosure minimises phase-mismatch and up-conversion simultaneously to achieve a high gain.

The TWPA device may further be configured to generate an idler signal, wherein said 3-wave mixing is implemented by configuring said TWPA device to satisfy: ωₛ<ωₚ and ωᵢ=ωₚ−ωₛ, in which ωₛ is a frequency of said amplification signal, ωₚ is a frequency of said pump signal and ωᵢ is a frequency of said idler signal.

Accordingly, such a configuration of said TWPA device may allow for the 3-wave mixing to be implemented efficiently.

The nonlinear inductance element may be a single Josephson junction, or a combination of at least two (i.e. a plurality) of Josephson junctions. Each Josephson junction may comprise a pair of superconducting elements coupled by a, compared to the superconducting elements, less conducting region/barrier. In other aspects, the nonlinear inductance element may be a kinetic inductance element.

An advantage of using Josephson junctions as a nonlinear inductance element is that the TWPA device will be a superconducting TWPA device that allows for minimised dissipation.

The resonator circuit may be an LC-oscillator. An LC oscillator may comprise an inductor element and a capacitor element connected. An LC-oscillator allows for an original frequency band to be split into two frequency bands (i.e. upper and lower). In other aspects, the resonator circuit may be a transmission line resonator, a quarter wavelength resonator or any other suitable type of resonator circuit.

The input parameters may be at least one of inductance and capacitance.

Further, the TWPA device is configured to receive an amplification signal having a frequency being in said lower frequency band. Accordingly, the pump signal will be in the upper frequency band so that any up-conversion within a certain band will be prevented.

Moreover, the TWPA device may be configured to satisfy/comply with criterias being:

ωₚ+ωₛ>ω_{c} and

$$2 {ω}_{p} - {ω}_{s} > {ω}_{c}$$

in which ωₛ is a frequency of said amplification signal, ωₚ is a frequency of said pump signal and ω_{c} is said cut-off frequency.

The TWPA device satisfying the above criteria will prevent up-conversion.

Further, when each cell comprises a resonator circuit (i.e. according to (i)) in each of said plurality of unit cells, the two-band dispersion relation may be defined by:

$${ω}_{\pm }^{2} = \frac{1}{2 v} [ ( {ω}_{r}^{2} + 4 {ω}_{0}^{2} {sin}^{2} \frac{κ}{2} ) \pm \sqrt{{( {ω}_{r}^{2} + 4 {ω}_{0}^{2} {sin}^{2} \frac{κ}{2} )}^{2} - 16 v {ω}_{r}^{2} {ω}_{0}^{2} {sin}^{2} \frac{κ}{2}} ]$$

and wherein when said when plurality of unit cells comprise periodically modulated input parameters (i.e. according to (ii)) said dispersion relation may be defined by:

$${ω}_{\pm }^{2} = ( {ω}_{1}^{2} + {ω}_{2}^{2} ) \pm \sqrt{{( {ω}_{1}^{2} + {ω}_{2}^{2} )}^{2} - 4 {ω}_{1}^{2} {ω}_{2}^{2} {sin}^{2} κ}$$

wherein ω₊ represents said upper frequency band, ω₋ represents said lower frequency band, wherein κ represents a wave value multiplied by a unit cell length being within a range of 0 to π, wherein ω₀ represents the resonance frequency of the TWPA, wherein or represents the resonance frequency of said resonator circuit, wherein ν represents a coupling factor being <1. Further, each unit cell comprises a first and a second subcell, wherein ω₁ represents the resonance frequency of each first subcell, and wherein ω₂ represents the resonance frequency of each second subcell.

A two-band dispersion relation in accordance with the above provides an advantage of allowing for the pump frequency to be configured to be close to/associated with said cut-off frequency while maintaining phase matching.

Periodical modulation of said plurality of unit cells may comprise a varying modulation of at least every other unit cell of said plurality of unit cells in said chain of unit cells. In other words, said chain of unit cells may extend along a row and every other unit cell thereof along the row may have varied input parameters compared to the rest of the unit cells along said row. In some aspects of the present disclosure every third, every fourth every fifth unit cell may have varied modulation. In some aspects the subcells of the unit cells may have different input parameters.

A benefit of this is that a two-band structure may be obtained without significant hardware penalty.

Further, the TWPA device may be configured to comply with/satisfy criterias being ωₚ>2ω_{c}/3, in which ωₚ is a frequency of said pump signal and ω_{c} is said cut-off frequency.

An advantage of such a configuration is that up-conversion will be inhibited for multiple signal frequencies while keeping the phase mismatch small.

It should be noted that the features herein may be combined in any manner even though not explicitly mentioned. E.g. any variation of said pump signal (i.e. pump signal having a frequency being in said upper frequency band and being at least ⅔ of a cut-off frequency of said TWPA device and pump signal having a frequency being in said lower frequency band, wherein a second harmonic thereof is within said frequency-gap) may be combined with any chained unit cell circuitry (i.e. a resonator circuit arranged in each of said plurality of unit cells and periodically modulated input parameters).

There is also provided a method for amplifying an amplification signal for achieving exponential spatial growth in an amplitude of said amplification signal. The method comprises the steps of:
providing a TWPA device according to any aspect herein.
-implementing 3-wave mixing in said TWPA device.
receiving, at an input of said TWPA device, an amplification signal for amplification.
receive a pump signal at said input for providing energy to said amplification signal.
outputting an amplified amplification signal from an output of said TWPA device.

Thus, the method provides an efficient TWPA device that allows for achieving exponential gain by minimising up-conversion and phase-mismatch.

### BRIEF DESCRIPTION OF THE DRAWINGS

In the following, the disclosure will be described in a non-limiting way and in more detail with reference to exemplary embodiments illustrated in the enclosed drawings, in which:

FIG. 1 illustrates an objective view of a TWPA device in accordance with aspects of the present disclosure;

FIG. 2A illustrates an objective view of a TWPA device with enlarged portion A of circuitry therein in accordance with different aspects of the present disclosure;

FIG. 2B illustrates an objective view of a TWPA device with enlarged portion B of circuitry-schematics therein in accordance with different aspects of the present disclosure;

FIG. 3 schematically illustrates aspects of the nonlinear inductance elements in accordance with aspects of the present disclosure;

FIG. 4 illustrates in a graph regions of absence/presence of up-conversion of pump signal, amplification signal and idler signal;

FIG. 5 illustrates a plot showing the dispersion relation for a TWPA device with a resonator circuit in each unit cell;

FIG. 6 illustrates the dispersion relation of a TWPA device comprising periodically modulated input parameters;

FIG. 7A illustrates a graph showing a gain coefficient for an amplification signal with zero detuning of a TWPA device in accordance with aspects of the present disclosure;

FIG. 7B illustrates a gain coefficient as a function of detuning for a TWPA device in accordance with aspects of the present disclosure; and

FIG. 8 schematically in the form of a flowchart illustrates a method for amplifying an amplification signal.

### DETAILED DESCRIPTION

In the following detailed description, some embodiments of the present disclosure will be described. However, it is to be understood that features of the different embodiments are exchangeable between the embodiments and may be combined in different ways, unless anything else is specifically indicated. Even though in the following description, numerous specific details are set forth to provide a more thorough understanding of the provided disclosure, it will be apparent to one skilled in the art that the embodiments in the present disclosure may be realized without these details. In other instances, well known constructions or functions are not described in detail, so as not to obscure the present disclosure.

In the following description of example embodiments, the same reference numerals denote the same or similar components.

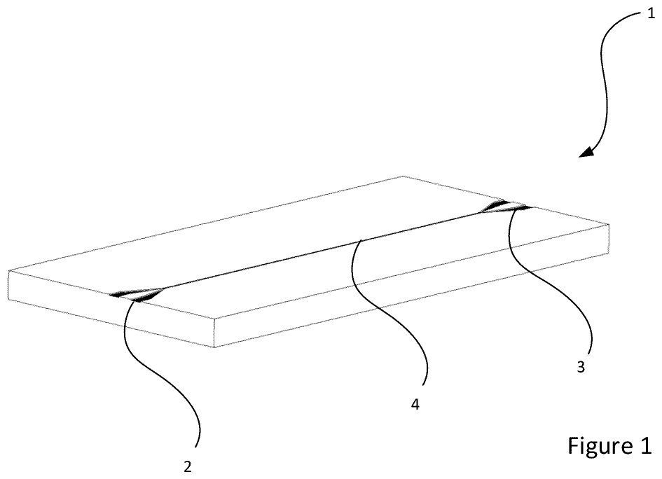

FIG. 1 illustrates an objective view of a TWPA device 1 for a quantum computer. The TWPA device 1 could for example be utilized for qubit readout. The TWPA device illustrated in FIG. 1 comprises an input 2, an output 3 and a transmission line 4 therebetween. The TWPA device 1 is configured to receive a pump signal and an amplification signal in said input 2 that propagates along the transmission line to said output 3 in which said amplification signal is amplified. The term “TWPA device” refers to an amplifier device utilizing an amplification principle based on nonlinear interaction of an amplification signal with an intense co-propagating wave (pump signal), which under a phase-matching condition results in spatial growth in the signal amplitude In the quantum regime, the TWPA is capable to generate signal squeezing and photon entanglement. The term “pump signal” refers to an alternating current signal that supplies energy required to amplify the amplification signal. Moreover, the output 3 of said TWPA device 1 may output said pump signal, amplifier amplification signal and an idler signal. The term “idler signal” refers to a signal at a frequency equal to the difference between the pump signal and amplification signal frequencies.

The TWPA device 1 according to the present disclosure comprises a two-band dispersion relation and is configured to implement 3-wave mixing in said two-band dispersion relation.

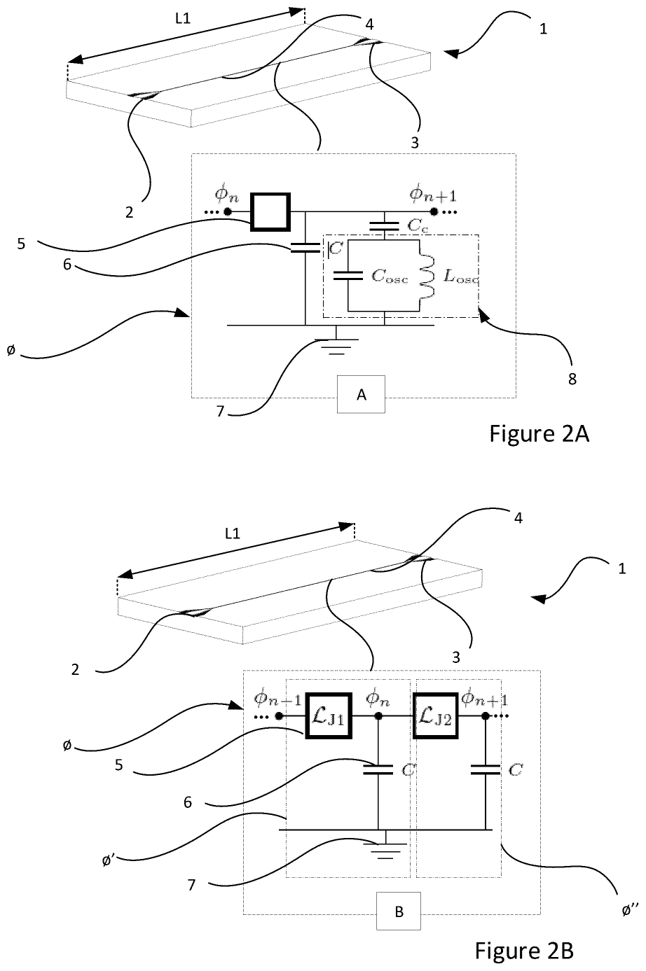

FIGS. 2A-2B illustrates in the enlarged portions A and B of said transmission line 4 that the TWPA device 1 comprises a plurality of chained unit cells ø, each unit cell ø comprising a nonlinear inductance element 5 and a capacitor 6 connected to a ground 7 thereof. The term “chained” refers to that the unit cells ø are connected so to extend along the length L1 of said TWPA device. Moreover, the chained unit cells ø further comprises one of:
(i) a resonator circuit 8 arranged in each of said plurality of unit cells ø and
(ii) periodically modulated input parameters.

FIG. 2A illustrates in an enlarged section A depicting an enlarged view of a part of said transmission line 4, that the chained unit cells ø comprises a resonator circuit 8. The resonator circuit 8 may be an LC-oscillator as shown in FIG. 2A.

FIG. 2B illustrates in enlarged section B depicting an enlarged view of a part of said transmission line 4 that the chained unit cell ø have periodically modulated input parameters. The input parameters may be at least one of inductance and capacitance. Thus, as illustrated in enlarged section B in FIG. 2B, each unit cell ø comprises of two subcells ø′, ø″. Thus, the non-linear inductance element 5 in each subcell ø′, ø″ may have different inductances. Accordingly, every other subcell ø′, ø″ in each unit cell ø may have different input parameters. In some aspects, periodical modulation of said plurality of unit cells ø comprises a varying modulation of at least every other unit cell ø of said plurality of unit cells ø in said chain of unit cells ø.

Moreover, the two-band dispersion relation of said TWPA device 1 is composed of a lower frequency band and an upper frequency band with a frequency-gap in-between said upper and lower frequency bands. The TWPA device 1 is further configured to receive an amplification signal for amplification, at an input 2 of said TWPA device 1 and receive a pump signal at said input 2 for providing energy to said amplification signal. The pump signal having a frequency being in said upper frequency band and being at least ⅔ of a cut-off frequency of said TWPA device 1 or said pump signal having a frequency being in said lower frequency band, wherein a second harmonic thereof is within said frequency-gap.

The phrase “implement 3-wave mixing” may refer to that the TWPA device 1 employ a lowest order, cubic, nonlinearity of inductive energy, (which is e.g., similar to the X⁽²⁾ nonlinearity in optical crystals). Such nonlinearity is associated with a broken time-reversal symmetry, which can be introduced by applying a dc current bias, or a magnetic flux bias. The amplification to said amplification signal consequently occurs due to a down-conversion process, which is capable to provide an efficient amplification within a large bandwidth in a weakly dispersive medium already at relatively small pump intensity of said pump signal. The 3-wave mixing of the TWPA device shown in FIGS. 1A-1B may be implemented by configuring said TWPA device to satisfy: ωₛ<ωₚ and ωᵢ=ωₚ−ωₛ, in which ωₛ is a frequency of said amplification signal, ωₚ is a frequency of said pump signal and ωᵢ is a frequency of an idler signal.

The nonlinear inductance element 5 may be a single Josephson junction, or a combination of at least two Josephson junctions.

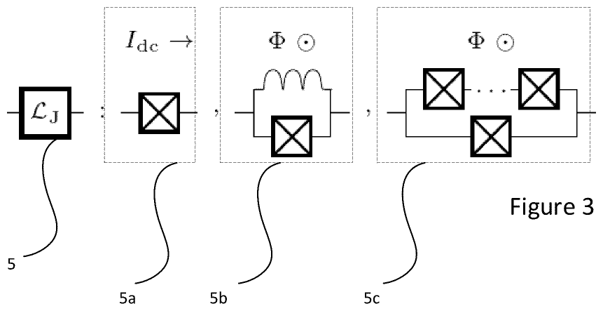

FIG. 3 schematically illustrates that the nonlinear inductance element 5 of the TWPA device 1 according to the present disclosure may be a Josephson junction 5a, a current biased junction, a flux-biased rf-SQUID or a flux-biased SNAIL. In case the nonlinear inductance element is a Josephson junction, said nonlinear inductance element may be biased with a dc current which induces a constant shift of the phase difference across each unit cell. Moreover, in case the nonlinear inductance element is a rf-SQUID or flux-biased snail, said nonlinear inductance element 5 may be biased with a dc magnetic field which induces a constant shift of the phase difference across each unit cell ø.

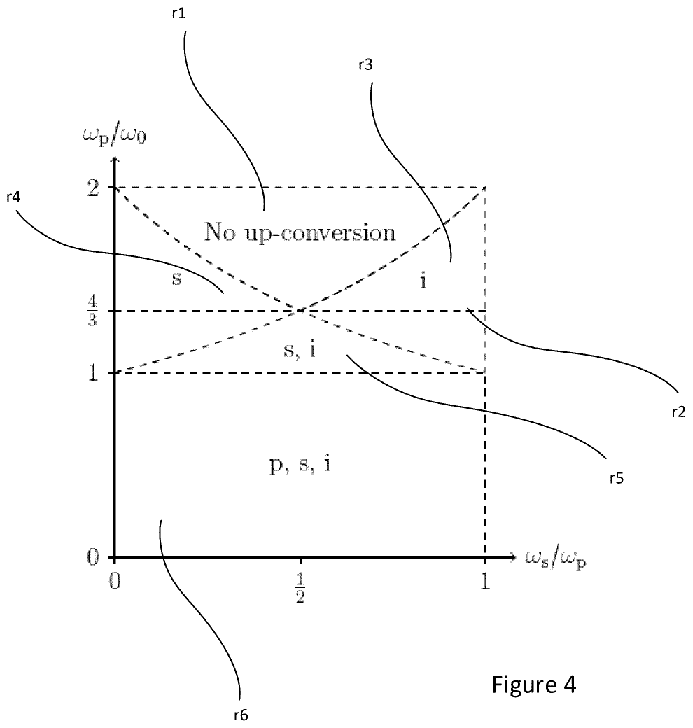

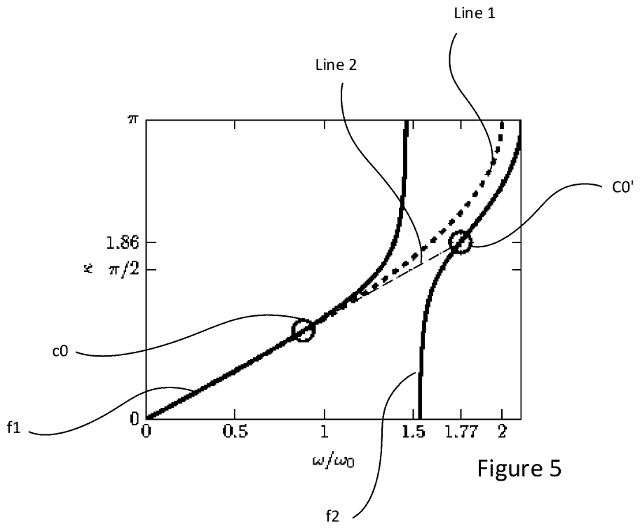

FIG. 4 illustrates a graph that shows a simulation of the performance of TWAP device for different frequencies of said amplification signal and pump signal as disclosed herein. FIGS. 5-7B illustrates simulation of the dispersion relation of the two-band structures according to aspects herein. The purpose of the simulations shown in FIGS. 4-7B is to further describe the disclosure as presented herein accompanied with advantages thereof. It should be noted that the simulations are based on aspects for a disclosing purpose, however it is not limited to said aspects and may be varied within the present disclosure.

FIG. 4 illustrates regions of absence/presence of up-conversion of pump signal, amplification signal and idler signal. In the region denoted r1 no up-conversion takes place, horizontal dashed line r2 indicates Ωₜₕ; in regions r3 and r4 (which is defined by everything in-between r1 and r5) up-conversion of either amplification signal or idler signal is possible. In region r5 both amplification signal and idler are up-converted whereas the pump signal is not. Region 6, r6 illustrates a region in which all three signals are up-converted. Thus, for the pump signal, the condition, ωₚ>ω₀ (ω₀ represents the resonance frequency of the TWPA device 1), guarantees that the second harmonic thereof falls above said cut-off frequency ω_{c}=2ω₀. For the signal/idler the lowest bound is established by condition that the up-converted signal at zero detuning falls above the cutoff, ωₚ+ωₚ/2>2ω₀. This yields a more stringent constraint, ωₚ>Ωₜₕ=4ω₀/3. At a pump frequency of said pump signal which is larger than said threshold value, the detuned signal and idler are not up-converted within the band defined by equation:

$$\vert δ \vert < 3 ( 1 - \frac{{Ω}_{th}}{{ω}_{p}} )$$

$$where$$

$$δ = \frac{{ω}_{s} - {ω}_{p} / 2}{{ω}_{p} / 2} .$$

Accordingly, FIG. 4 validates that, by adjusting said pump signal to have a frequency being in said upper frequency band and being at least ⅔ of a cut-off frequency of said TWPA device 1, no up-conversion will take place.

FIG. 5 illustrates a graph that shows the dispersion relation for a TWPA device 1 with a resonator circuit 8 (as shown in FIG. 2A) in each unit cell ø. Accordingly, FIG. 5 illustrates the two-band dispersion relation of said TWPA device 1 that is composed of/comprises a lower frequency band f1 and an upper frequency band f2 with a frequency-gap in-between said upper and lower frequency bands f1, f2. The dashed line, Line 1 shows the dispersion relation without the added resonance circuit and the circles c0, c0′ show a sweet spot for both the pump signal and the amplification signal, where they are perfectly phase matched while no up-conversion is possible. Moreover, the dispersion relation exhibits said frequency-gap at a resonance frequency of the resonance circuit 8. As noted above, the circles c0, c0′ indicate the positions of phase matched points which lie on a straight line, line 2, within the no-up-conversion region. This ensures that the phase mismatch is zero for an amplification signal with a frequency of half of the pump frequency, and a small phase mismatch for other amplification signal frequencies. Thus, in accordance with the disclosure of FIG. 5, in some aspects of the disclosure, the sweet spot, which prevents up-conversion while providing exponential gain, requires that a pump frequency of the pump signal is within the upper band f2 (preferably at c0′), and a signal frequency of the amplification signal within the lower band f1 (preferably at c0). Thus, the TWPA device 1 may be configured to comply with ωₚ>2ω_{c}/3, in which ωₚ is a frequency of said pump signal and ω_{c} is said cut-off frequency.

However, as noted herein, in some aspects, a pump frequency of the pump signal may be in said lower frequency band f1, wherein a second harmonic thereof is within said frequency-gap.

The two-band dispersion relation as illustrated in FIG. 5, may be defined at aspects when each cell ø comprises a resonator circuit 8 in each of said plurality of unit cells ø:

$${ω}_{\pm }^{2} = \frac{1}{2 v} [ ( {ω}_{r}^{2} + 4 {ω}_{0}^{2} {sin}^{2} \frac{κ}{2} ) \pm \sqrt{{( {ω}_{r}^{2} + 4 {ω}_{0}^{2} {sin}^{2} \frac{κ}{2} )}^{2} - 16 v {ω}_{r}^{2} {ω}_{0}^{2} {sin}^{2} \frac{κ}{2}} ]$$

Moreover, when said when plurality of unit cells ø comprise periodically modulated input parameters said dispersion relation may be defined by:

$${ω}_{\pm }^{2} = ( {ω}_{1}^{2} + {ω}_{2}^{2} ) \pm \sqrt{{( {ω}_{1}^{2} + {ω}_{2}^{2} )}^{2} - 4 {ω}_{1}^{2} {ω}_{2}^{2} {sin}^{2} κ}$$

wherein w₊ represents said upper frequency band, ω₋ represents said lower frequency band, wherein κ represents a wave value multiplied by a unit cell length being within a range of 0 to π, wherein ω₀ represents the resonance frequency of the TWPA, wherein ωᵣ represents the resonance frequency of said resonator circuit, wherein ν represents a coupling factor being <1, wherein each unit cell comprises a first and a second subcell, wherein ω₁ represents the resonance frequency of each first subcell ø′, and wherein ω₂ represents the resonance frequency of each second subcell ø″ (see FIG. 2B). The term coupling factor may refer to an electrical coupling in-between a resonator circuit and the unit cells of said TWPA device 1.

The coupling factor is given by

$$v = 1 - \frac{{C}_{c}}{C + {C}_{c}} \frac{{C}_{c}}{{C}_{osc} + {C}_{c}}$$

where a coupling ν=1 corresponds to a completely disconnected resonator circuit (e.g. an LC-oscillator), while smaller values ν<1 correspond to a connected resonator circuit e.g., an LC-oscillator. C_{c} is a capacitance of a capacitor serially connected with a resonator circuit, C_{osc} is a capacitance of a capacitor of said resonator circuit and C is a capacitance of a capacitor connected to a ground. See e.g. FIG. 2A.

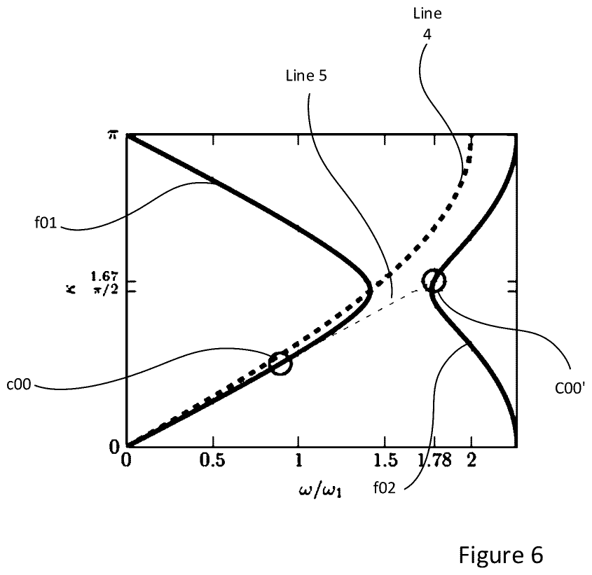

FIG. 6 illustrates the dispersion relation of a TWPA device comprising periodically modulated input parameters with ω₂=1.25ω₁; comprising of two bands f01, f02 separated by a gap. Line 4 indicates the dispersion relation in the absence of modulation, the circles c00, c00′ indicate positions of phase matched points jointly forming a straight line, line 5, within the no-up-conversion frequency region. This ensures that the phase mismatch is zero for an amplification signal with a frequency of half of the pump frequency, and a small phase mismatch for other amplification signal frequencies. The positions of the pump signal and the amplification signal at the degeneracy are indicated with the circles, c00 showing the amplification signal and c00′ showing the pump signal. The gain in this setup is qualitatively similar to the aspect of the TWPA device 1 with resonance circuit 8 (as shown in FIG. 5) i.e. providing an exponential gain.

In the aspect of the disclosure in which said pump signal has a frequency being in said lower frequency band, wherein a second harmonic thereof is within said frequency-gap. The pump signal could for instance be placed so that wp is 1.5/2 in the graph of FIG. 6. Consequently, the up-converted pump frequency will be in said gap (in between f01 and f02) thus preventing up conversion.

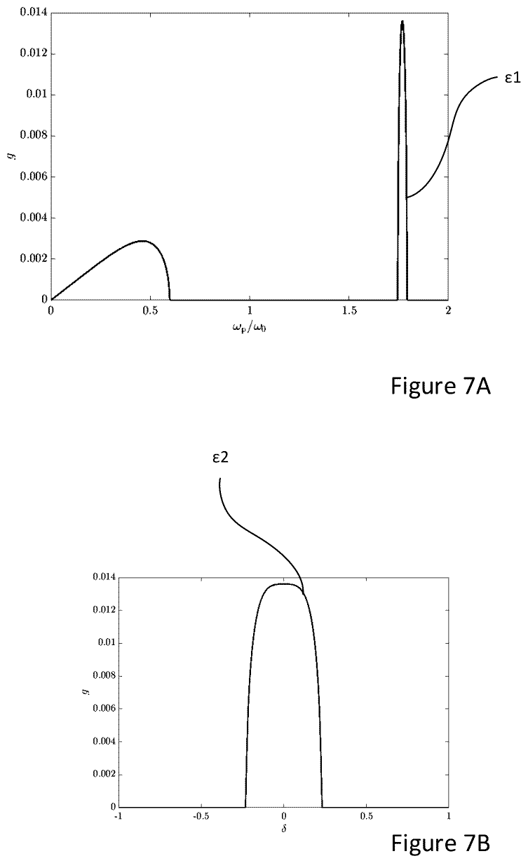

FIG. 7A illustrates a gain coefficient, of a TWPA device 1 in accordance with aspects of the present disclosure, for a signal at zero detuning with ωᵣ=1.5, ω₀, ν=0.95, ε₁=0.06 When the pump is placed within the lower band, the gain coefficient is similar to the case in the absence of oscillators (curves at the lower left corner in FIG. 7A). In some aspects, the sharp high-amplification peak emerges when the pump is placed within the upper band at the sweet spot, ωₚ=1.77ω₀. The peak width is 0.048ω₀.

FIG. 7B illustrates a gain coefficient, of a TWPA device 1 in accordance with aspects of the present disclosure, as a function of detuning in which ωᵣ=1.5, ν=0.95 for a pump signal at an optimal phase matching point ωₚ=1.770, and pumping strength of ε₂=0.06. The corresponding bandwidths is ωₛ−ωₚ/2=0.23ωₚ. In accordance with the disclosure of FIG. 7B, given a pump strength of ε₁=0.06 the amplification signal may have a frequency being in a range of 4.6-7.4 GHz, preferably 6 GHz. Then the pump signal may have a frequency being about 12 GHz (ωₚ=2ωₛ). Accordingly, the cutoff frequency may be about 14 GHz if said pump frequency is about 12 GHz and said amplification signal is about 6 GHz so to provide exponential gain in accordance with aspects of the present disclosure. However, it should be noted that the above is merely for a disclosing purpose and is not limiting for the disclosure.

Thus, the FIGS. 7A to 7B illustrates that the present disclosure allows for pure exponential growth of the amplification signal of the TWPA device 1 herein with minimum added noise for a wide band.

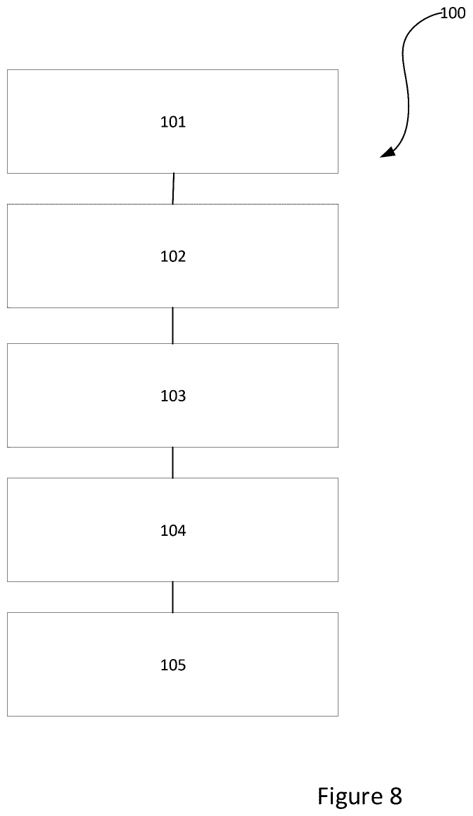

FIG. 8 schematically in the form of a flowchart illustrates a method 100 for amplifying an amplification signal for achieving exponential spatial growth in an amplitude of said amplification signal. The method 100, comprising
providing 101 a TWPA device 1 according to any aspect herein (e.g. as shown in FIGS. 1-2B);
implementing 102 3-wave mixing in said TWPA device 1;
receiving 103, at an input 2 of said TWPA device, an amplification signal for amplification;
receiving 104 a pump signal at said input 2 for providing energy to said amplification signal;
outputting 105 an amplified amplification signal from an output of said TWPA device 1.

1. A travelling-wave parametric amplifier, TWPA, device for a quantum computer, wherein the TWPA has a two-band dispersion relation, wherein the TWPA device is configured to implement 3-wave mixing in said two-band dispersion relation, the TWPA device comprising:
a plurality of chained unit cells, each unit cell comprising a nonlinear inductance element and a capacitor connected to a ground thereof, wherein said chained unit cells further comprises one of:
a resonator circuit arranged in each of said plurality of unit cells; and
periodically modulated input parameters;
wherein the two-band dispersion relation comprises a lower frequency band and an upper frequency band with a frequency-gap in-between said upper and lower frequency bands;
wherein the TWPA device is further configured to:
receive an amplification signal for amplification, at an input of said TWPA device;
receive a pump signal at said input for providing energy to said amplification signal;
said pump signal having a frequency being in said upper frequency band and being at least ⅔ of a cut-off frequency of said TWPA device, or;
said pump signal having a frequency being in said lower frequency band, wherein a second harmonic thereof is within said frequency-gap.

2. The TWPA device according to claim 1, being further configured to generate an idler signal, wherein said 3-wave mixing is implemented by configuring said TWPA device to satisfy: ωₛ<ωₚ and ωᵢ=ωₚ−ωₛ, in which ωₛ is a frequency of said amplification signal, ωₚ is a frequency of said pump signal and ωᵢ is a frequency of said idler signal.

3. The TWPA device according to claim 1, wherein the nonlinear inductance element is a single Josephson junction, or a combination of at least two Josephson junctions.

4. The TWPA device according to claim 1, wherein said resonator circuit is an LC-oscillator.

5. The TWPA device according to claim 1, wherein said input parameters is at least one of inductance and capacitance.

6. The TWPA device according to claim 1, wherein the TWPA device is configured to receive an amplification signal having a frequency being in said lower frequency band.

7. The TWPA device according to claim 1, wherein when each cell comprises a resonator circuit in each of said plurality of unit cells, the two-band dispersion relation is defined by:
$${ω}_{\pm }^{2} = \frac{1}{2 v} [ ( {ω}_{r}^{2} + 4 {ω}_{0}^{2} {sin}^{2} \frac{κ}{2} ) \pm \sqrt{{( {ω}_{r}^{2} + 4 {ω}_{0}^{2} {sin}^{2} \frac{κ}{2} )}^{2} - 16 v {ω}_{r}^{2} {ω}_{0}^{2} {sin}^{2} \frac{κ}{2}} ]$$
and wherein when said when plurality of unit cells comprise periodically modulated input parameters said dispersion relation is defined by:
$${ω}_{\pm }^{2} = ( {ω}_{1}^{2} + {ω}_{2}^{2} ) \pm \sqrt{{( {ω}_{1}^{2} + {ω}_{2}^{2} )}^{2} - 4 {ω}_{1}^{2} {ω}_{2}^{2} {sin}^{2} κ}$$
wherein ω₊ represents said upper frequency band, ω₋ represents said lower frequency band, wherein κ represents a wave value multiplied by a unit cell length being within a range of 0 to π, wherein ω₀ represents the resonance frequency of the TWPA, wherein ωᵣ represents the resonance frequency of said resonator circuit, wherein ν represents a coupling factor being <1, wherein each unit cell comprises a first and a second subcell, wherein ω₁ represents the resonance frequency of each first subcell, and
wherein ω₂ represents the resonance frequency of each second subcell.

8. The TWPA device according to claim 1, wherein periodical modulation of said plurality of unit cells comprises a varying modulation of at least every other unit cell of said plurality of unit cells in said chain of unit cells.

9. The TWPA device according to claim 1, wherein the TWPA device is configured to comply with criteria being: ωₚ+ωₛ>ω_{c} and 2*ωₚ−ωₛ>ω_{c} in which ωₛ is a frequency of said amplification signal, ωₚ is a frequency of said pump signal and ω_{c} is said cut-off frequency.

10. A method for amplifying an amplification signal for achieving exponential spatial growth in an amplitude of said amplification signal comprising:
providing a TWPA device according to claim 1;
implementing 3-wave mixing in said TWPA device;
receiving, at an input of said TWPA device, an amplification signal for amplification;
receiving a pump signal at said input for providing energy to said amplification signal;
outputting an amplified amplification signal from an output of said TWPA device.
